(19) United States
(12) Patent Application Publication
(10) Pub. No.: US 2025/0254935 A1
(43) Pub. Date: Aug. 7, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Ryota SUZUKI, Nisshin-shi (JP)

(21) Appl. No.: 18/946,530

(22) Filed: Nov. 13, 2024

(30) Foreign Application Priority Data
Feb. 6, 2024 (JP) 2024-016558

(51) Int. Cl. H01L 29/06; H01L 29/66; H01L 29/78

(52) U.S. Cl. CPC H10D 62/111; H10D 30/668; H10D 30/0291

(57) ABSTRACT

A semiconductor substrate has a first conductivity type upper region, a second conductivity type electric field relaxation region, a superjunction region, and first conductivity type connection regions. A second conductivity type column region and a first conductivity type column region of the superjunction region extend linearly along a first direction and are alternately arranged in a second direction. The electric field relaxation region has openings in a dispersed manner. The first conductivity type connection regions are respectively disposed in the openings to connect the first conductivity type upper region to the corresponding first conductivity type column region. A concentration of second conductivity type impurity in the second conductivity type column region is lower than that of the electric field relaxation region. When the semiconductor substrate is viewed from the upper side, the second conductivity type column regions do not overlap with the openings.

### CROSS REFERENCE TO RELATED APPLICATION

This application is based on Japanese Patent Application No. 2024-016558 filed on Feb. 6, 2024, the disclosure of which is incorporated herein by reference.

### TECHNICAL FIELD

The present disclosure relates to a semiconductor device.

### BACKGROUND

A metal-oxide-semiconductor field-effect transistor (MOSFET) includes a semiconductor substrate, a source electrode, and a drain electrode. The semiconductor substrate has an upper parallel pn structure and a lower parallel pn structure. The upper parallel pn structure has upper p-type column regions and upper n-type column regions.

### SUMMARY

According to an aspect of the present disclosure, a semiconductor device includes a semiconductor substrate, an upper electrode provided on an upper surface of the semiconductor substrate, and a lower electrode provided on a lower surface of the semiconductor substrate, such that current flows between the upper electrode and the lower electrode. The semiconductor substrate has: a first conductivity type upper region; a second conductivity type electric field relaxation region disposed below the first conductivity type upper region to be connected to the upper electrode; a superjunction region disposed below the electric field relaxation region, and a plurality of first conductivity type connection regions. The superjunction region has a plurality of second conductivity type column regions and a plurality of first conductivity type column regions. When the semiconductor substrate is viewed from the upper side, the second conductivity type column region and the first conductivity type column region extend linearly along a first direction and are alternately arranged in a second direction perpendicular to the first direction. The electric field relaxation region has a plurality of openings penetrating the electric field relaxation region from an upper end to a lower end. The plurality of openings is distributed within a plane parallel to the upper surface of the semiconductor substrate. The first conductivity type connection regions are respectively disposed in the openings to connect the first conductivity type upper region to the first conductivity type column regions. A concentration of second conductivity type impurity in each of the second conductivity type column regions is lower than that in the electric field relaxation region. When the semiconductor substrate is viewed from the upper side, the second conductivity type column regions do not overlap the openings.

### BRIEF DESCRIPTION OF DRAWINGS

FIG. 1 is a perspective and cross-sectional view of a semiconductor device according to a first embodiment.

FIG. 2 is a plan view taken along a plane II in FIG. 1.

FIG. 3 is a plan view taken along a plane III in FIG. 1.

FIG. 4 is a diagram for explaining a manufacturing process of the semiconductor device of the first embodiment.

FIG. 5 is a diagram for explaining a manufacturing process of the semiconductor device of the first embodiment.

FIG. 6 is a diagram for explaining a manufacturing process of the semiconductor device of the first embodiment.

FIG. 7 is a diagram for explaining a manufacturing process of the semiconductor device of the first embodiment.

FIG. 8 is a perspective and cross-sectional view of a semiconductor device according to a second embodiment.

FIG. 9 is a cross-sectional view of a semiconductor device according to a third embodiment.

FIG. 10 is a plan view of the semiconductor device of the third embodiment.

FIG. 11 is a plan view taken along a plane XI of FIG. 9.

FIG. 12 is a plan view taken along a plane XII of FIG. 9.

FIG. 13 is a cross-sectional view of a semiconductor device according to a fourth embodiment.

FIG. 14 is a plan view of the semiconductor device of the fourth embodiment.

FIG. 15 is a plan view taken along a plane XV of FIG. 13.

FIG. 16 is a plan view taken along a plane XVI of FIG. 13.

### DETAILED DESCRIPTION

A metal-oxide-semiconductor field-effect transistor (MOSFET) includes a semiconductor substrate, a source electrode, and a drain electrode. In this MOSFET, the semiconductor substrate has an upper parallel pn structure and a lower parallel pn structure. The upper parallel pn structure has an upper p-type column region and an upper n-type column region. The upper p-type column region and the upper n-type column region extend linearly along a first direction, when the semiconductor substrate is viewed from the upper side, and are alternately arranged in a second direction perpendicular to the first direction. The lower parallel pn structure is disposed below the upper parallel pn structure, and has a lower p-type column region and a lower n-type column region. The lower p-type column region and the lower n-type column region extend linearly along the second direction, when the semiconductor substrate is viewed from the upper side, and are alternately arranged in the first direction.

When this MOSFET is turned off, the electric field applied to the gate oxide film is relaxed by the depletion layer extending from the upper p-type column region to the upper n-type column region. When this MOSFET is turned off, a depletion layer quickly spreads laterally from the pn junction at the interface between the upper p-type column region and the upper n-type column region, and from the pn junction at the interface between the lower p-type column region and the lower n-type column region. Therefore, this MOSFET can ensure a high breakdown voltage.

The upper p-type column region and the upper n-type column region extend linearly and are arranged alternately. In such a configuration, there is a limit to fine the pitch in each of the upper parallel pn structure and the lower parallel pn structure. Therefore, if the n-type impurity concentration of each n-type column region is increased in order to reduce the on-resistance, the n-type column region becomes difficult to deplete when the MOSFET is turned off, and the breakdown voltage of the MOSFET decreases. As described above, it is difficult to simultaneously ensure a high breakdown voltage and a low on-resistance. This specification proposes a technique for ensuring a high breakdown voltage and reducing the on-resistance.

According to an aspect of the present disclosure, a semiconductor device includes a semiconductor substrate, an upper electrode provided on an upper surface of the semiconductor substrate, and a lower electrode provided on a lower surface of the semiconductor substrate, such that current flows between the upper electrode and the lower electrode. The semiconductor substrate has: a first conductivity type upper region; a second conductivity type electric field relaxation region disposed below the first conductivity type upper region and connected to the upper electrode; a superjunction region disposed below the electric field relaxation region, and a plurality of first conductivity type connection regions. The superjunction region has a plurality of second conductivity type column regions and a plurality of first conductivity type column regions. When the semiconductor substrate is viewed from the upper side, the second conductivity type column region and the first conductivity type column region extend linearly along a first direction and are alternately arranged in a second direction perpendicular to the first direction. The electric field relaxation region has a plurality of openings penetrating the electric field relaxation region from an upper end to a lower end. The plurality of openings is distributed and arranged within a plane parallel to the upper surface of the semiconductor substrate. The first conductivity type connection regions are respectively disposed in the openings to connect the first conductivity type upper region to the first conductivity type column region. A second conductivity type impurity concentration in each of the second conductivity type column regions is lower than that in the electric field relaxation region. When the semiconductor substrate is viewed from the upper side, the second conductivity type column regions do not overlap the openings.

In this specification, the first conductivity type is either n-type or p-type, and the second conductivity type is the other of n-type and p-type. When the first conductivity type is n-type, the second conductivity type is p-type. When the first conductivity type is p-type, the second conductivity type is n-type.

In the semiconductor device, the openings are provided in the electric field relaxation region of the second conductivity type, and the first conductivity type connection region is provided within the opening. Since the electric field relaxation region is connected to the upper electrode, when the semiconductor device is turned off, a reverse voltage is applied to the pn junction at the interface between the electric field relaxation region and the first conductivity type semiconductor region (the first conductivity type upper region, the first conductivity type connection region, and the first conductivity type column region). As a result, a depletion layer spreads from the electric field relaxation region to the semiconductor region of the first conductivity type, and the electric field applied within the semiconductor region is relaxed. Furthermore, since the openings provided in the electric field relaxation region are dispersed in a plane parallel to the upper surface of the semiconductor substrate, the first conductivity type connection region can be more finely divided in the plane compared to a comparative example in which the second conductivity type regions and the first conductivity type regions are arranged alternately in stripes. Therefore, even if the first conductivity type impurity concentration in the first conductivity type connection region is increased, when the semiconductor device is turned off, a depletion layer spreads from the electric field relaxation region to almost the entire area of the first conductivity type connection region. In this manner, in this semiconductor device, the first conductivity type impurity concentration in the first conductivity type connection region can be made sufficiently high, thereby reducing the on-resistance.

In this semiconductor device, the superjunction region is disposed below the electric field relaxation region. The second conductivity type column region and the first conductivity type column region of the superjunction region extend linearly in the first direction and are alternately arranged in the second direction. When the semiconductor device is turned off, a depletion layer spreads from the pn junction at the interface between the second conductivity type column region and the first conductivity type column region into the second conductivity type column region and the first conductivity type column region. Since the second conductivity type column regions and the first conductivity type column regions are arranged in a stripe pattern, when the semiconductor device is turned off, the second conductivity type column regions and the first conductivity type column regions (i.e., the superjunction regions) are likely to be uniformly depleted. This makes it possible for the semiconductor device to ensure a high breakdown voltage. Furthermore, in this semiconductor device, since the second conductivity type column regions are provided at positions that do not overlap with the openings, the current path is not restricted by the second conductivity type column regions. Therefore, current flows suitably from the lower electrode through the first conductivity type column region, the first conductivity type connection region, and the first conductivity type upper region to the upper electrode, suppressing deterioration of the on-resistance. As described above, in this semiconductor device, a high breakdown voltage can be ensured and the on-resistance can be reduced.

For example, when the semiconductor substrate is viewed from the upper side, the openings may be arranged to form rows spaced apart from each other along the first direction. The rows may be spaced apart from each other in the second direction. The openings may be spaced equally apart from each other in the first direction. The intervals between the adjacent rows in the second direction may be equal to each other.

In such a configuration, the first conductivity type connection regions in the respective openings are regularly arranged in the plane. This makes it possible to make the on-resistance uniform over the entire semiconductor device.

For example, the superjunction region is a first superjunction region. The semiconductor device may further include a second superjunction region disposed below the first superjunction region. The second superjunction region may include a plurality of second conductivity type column regions and a plurality of first conductivity type column regions. When the semiconductor substrate is viewed from the upper side, the second conductivity type column region and the first conductivity type column region of the second superjunction region may extend linearly along a third direction intersecting the first direction, and may be arranged alternately in a fourth direction perpendicular to the third direction. The second conductivity type impurity concentration of each of the second conductivity type column regions may be lower than that of the electric field relaxation region.

In such a configuration, by further providing the second superjunction region, the overall length of the superjunction region in the thickness direction of the semiconductor substrate can be increased, thereby ensuring a higher breakdown voltage. The second conductivity type column region and the first conductivity type column region of the first superjunction region are arranged to intersect with the second conductivity type column region and the first conductivity type column region of the second superjuntion region respectively. Therefore, even if a positional deviation occurs between the first superjunction region and the second superjunction region, it is possible to suppress variation in the area of the current path.

For example, the semiconductor device may further have a second conductivity type connection region extending upward from an upper surface of the electric field relaxation region to connect the electric field relaxation region to the upper electrode.

In such a configuration, the potential of the electric field relaxation region can be easily fixed to the potential of the upper electrode while allowing the electric field relaxation region to exhibit its function.

For example, the semiconductor device may further have a trench in the upper surface of the semiconductor substrate, a gate insulating film covering an inner surface of the trench, and a gate electrode provided in the trench and insulated from the semiconductor substrate by the gate insulating film. The semiconductor substrate may further include a first conductivity type source region exposed to the upper surface of the semiconductor substrate and in contact with the gate insulating film, and a second conductivity type body region in contact with the gate insulating film below the source region to separate the first conductivity type upper region from the source region. The first conductivity type upper region may be in contact with the gate insulating film below the body region. When the semiconductor substrate is viewed from the upper side, the openings do not have to overlap with the trench.

In such a configuration, when the semiconductor substrate is viewed from the upper side, each opening is provided at a position that does not overlap with the trench (that is, the electric field relaxation region overlaps with the trench). Therefore, when the semiconductor device is turned off, the electric field applied to the bottom end of the trench can be suitably relaxed by the electric field relaxation region.

For example, the semiconductor device may further have a gate electrode on the upper surface of the semiconductor substrate via a gate insulating film. The semiconductor substrate may further include a source region of a first conductivity type exposed at the upper surface of the semiconductor substrate, and a body region of a second conductivity type adjacent to the source region and exposed at the upper surface of the semiconductor substrate. The first conductivity type upper region may be provided adjacent to the body region, separated from the source region by the body region, and exposed at the upper surface of the semiconductor substrate. The gate electrode may face the first conductivity type upper region via the gate insulating film, and may also face the body region located between the source region and the first conductivity type upper region. When the semiconductor substrate is viewed from the upper side, each of the openings may overlap the gate electrode.

In such a configuration, when the semiconductor device is turned on, a channel is formed in the body region within a range facing the gate electrode, and electrons flow from the source region through the channel to the first conductivity type upper region. In this configuration, when the semiconductor substrate is viewed from the upper side, each opening is provided at a position overlapping with the gate electrode. That is, each opening is provided at a position overlapping the first conductivity type upper region facing the gate electrode. Therefore, the current path from the first conductivity type connection region in each opening through the first conductivity type upper region, the channel, and the source region is short, so as to reduce the on-resistance.

In the semiconductor device, for example, the first conductivity type upper region may be exposed at the upper surface of the semiconductor substrate. The upper electrode and the upper surface of the semiconductor substrate may form a Schottky junction. When the semiconductor substrate is viewed from the upper side, each opening may overlap a Schottky junction surface.

In such a configuration, when the semiconductor substrate is viewed from the upper side, each opening is provided at a position overlapping with a Schottky junction surface. Therefore, the current path from the Schottky junction surface through the first conductivity type upper region, the first conductivity type connection region in the opening, and the first conductivity type column region is short, making it possible to reduce the on-resistance.

### First Embodiment

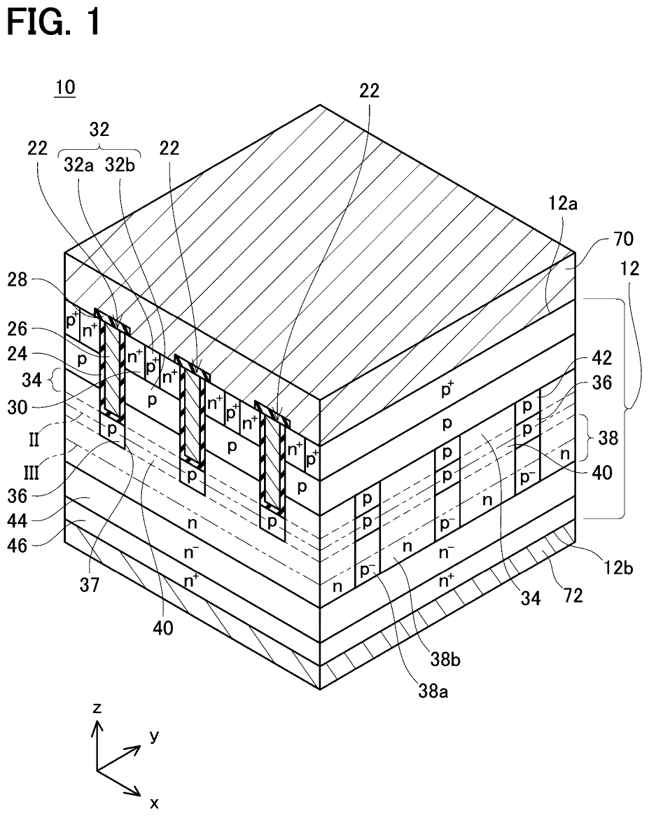

A semiconductor device 10 according to a first embodiment will be described below with reference to the drawings. A semiconductor device 10 shown in FIG. 1 is a vertical metal-oxide-semiconductor field-effect transistor (MOSFET), and includes a semiconductor substrate 12, electrodes, and an insulating film. The semiconductor substrate 12 is made of SiC. However, the material constituting the semiconductor substrate 12 is not particularly limited, and may be other semiconductor materials such as Si or GaN. Hereinafter, a direction parallel to the upper surface 12a of the semiconductor substrate 12 is referred to as x direction, and a direction parallel to the upper surface 12a of the semiconductor substrate 12 and perpendicular to the x direction is referred to as y direction. A thickness direction of the semiconductor substrate 12 is referred to as z direction.

Trenches 22 are formed in the upper surface 12a of the semiconductor substrate 12. As shown in FIG. 1, the trenches 22 are spaced apart from each other in the x direction. Each trench 22 extends longitudinally in the y direction. A gate insulating film 24 and a gate electrode 26 are disposed in each of the trenches 22. The gate insulating film 24 covers an inner surface of each of the trenches 22. The gate electrode 26 is insulated from the semiconductor substrate 12 by the gate insulating film 24. An upper surface of the gate electrode 26 is covered with an interlayer insulating film 28. A source electrode 70 is disposed on the upper surface 12a of the semiconductor substrate 12. The source electrode 70 is in contact with the upper surface 12a of the semiconductor substrate 12 in a portion where the interlayer insulating film 28 is not provided. The source electrode 70 is insulated from the gate electrode 26 by the interlayer insulating films 28. A drain electrode 72 is arranged on a lower surface 12b of the semiconductor substrate 12. The drain electrode 72 is in contact with substantially the entire lower surface 12b of the semiconductor substrate 12.

Inside the semiconductor substrate 12, there are provided plural source regions 30, a body region 32, an n-type upper region 34, an electric field relaxation region 36, a superjunction (hereinafter referred to as “SJ”) region 38, plural n-type connection regions 40, plural p-type connection regions 42, a drift region 44, and a drain region 46.

Each of the source regions 30 is n-type and is exposed to the upper surface 12a of the semiconductor substrate 12. Each of the source regions 30 is in ohmic contact with the source electrode 70. Each of the source regions 30 is in contact with the gate insulating film 24 at the upper end of the trench 22.

The body region 32 is p-type, and includes a contact region 32a and a main region 32b. The contact region 32a is exposed to the upper surface 12a of the semiconductor substrate 12 and is in ohmic contact with the source electrode 70. The contact region 32a is disposed in a range between the two source regions 30. The contact region 32a extends longitudinally along the y direction. The main region 32b is disposed below the source region 30 and the contact region 32a. The main region 32b is in contact with the gate insulating film 24 below the source region 30. The p-type impurity concentration of the main region 32b is lower than the p-type impurity concentration of the contact region 32a.

The n-type upper region 34 is disposed below the body region 32. The n-type upper region 34 is separated from each of the source regions 30 by the body region 32. The n-type upper region 34 is in contact with the gate insulating film below the body region 32 in an area where the p-type connection region 42 (described later) does not exist.

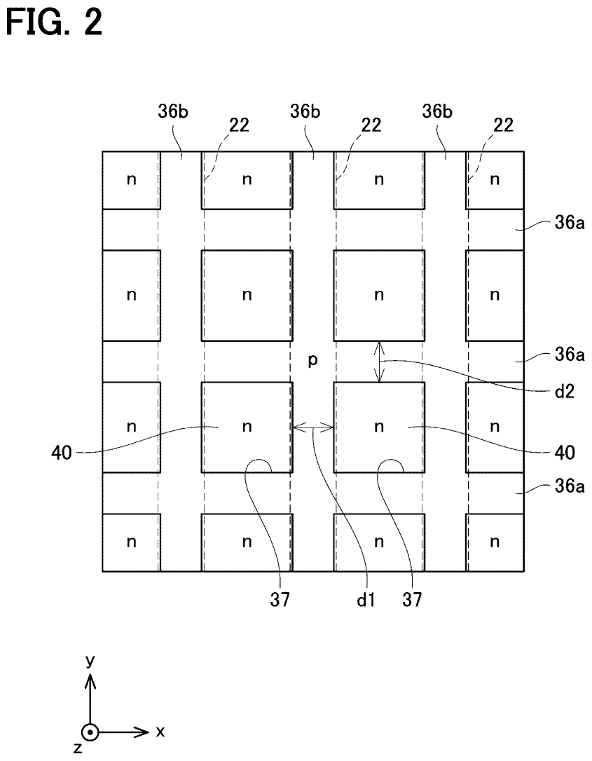

The electric field relaxation region 36 is p-type, and is disposed below the n-type upper region 34. As shown in FIG. 2, the electric field relaxation region 36 is composed of plural x-direction portions 36a extending in the x direction and plural y-direction portions 36b extending in the y direction when the semiconductor substrate 12 is viewed from the upper side. Each of the y-direction portions 36b is disposed in a range exposed to the bottom surface of the corresponding trench 22. Each of the y-direction portions 36b is in contact with the gate insulating film 24 at the bottom surface of the trench 22. The electric field relaxation region 36 is made of the plural x-direction portions 36a and the plural y-direction portions 36b arranged in a lattice pattern. The electric field relaxation region 36 has plural openings 37 formed therein. The openings 37 are arranged in a dispersed manner within the plane shown in FIG. 2. Specifically, each opening 37 is formed by two y-direction portions 36b adjacent to each other in the x direction and two x-direction portions 36a adjacent to each other in the y direction. Therefore, each opening 37 does not overlap with the trench 22 when the semiconductor substrate 12 is viewed from the upper side. The intervals d1 between the adjacent openings 37 in the x direction are equal to each other. The intervals d2 between the adjacent openings 37 in the y direction are equal to each other. Each opening 37 penetrates the electric field relaxation region 36 from its upper end to its lower end. The n-type connection region 40 is disposed within each opening 37.

The SJ region 38 is disposed below the electric field relaxation region 36. The SJ region 38 has plural p-type column regions 38a and plural n-type column regions 38b.

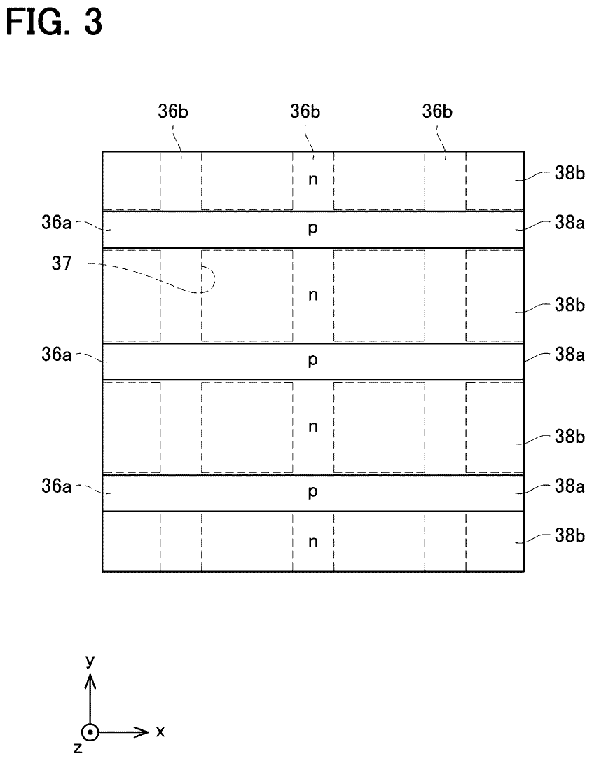

As shown in FIG. 3, when the semiconductor substrate 12 is viewed from the upper side, the p-type column region 38a and the n-type column region 38b extend linearly along the x direction and are arranged alternately in the y direction. The p-type impurity concentration of each p-type column region 38a is lower than the p-type impurity concentration of the electric field relaxation region 36. Each p-type column region 38a is disposed directly below the x-direction portion 36a of the electric field relaxation region 36 and is connected to the x-direction portion 36a. That is, when the semiconductor substrate 12 is viewed from the upper side, each p-type column region 38a does not overlap the openings 37.

As shown in FIG. 1, each n-type connection region 40 is disposed within a corresponding opening 37, as described above. Each n-type connection region 40 connects the n-type upper region 34 and the corresponding n-type column region 38b.

When the semiconductor substrate 12 is viewed from the upper side, each p-type connection region 42 extends linearly in the x direction. Each p-type connection region 42 is disposed directly above the x-direction portion 36a of the electric field relaxation region 36. That is, when the semiconductor substrate 12 is viewed from the upper side, each p-type connection region 42 does not overlap the openings 37. Each p-type connection region 42 extends upward from the top surface of the electric field relaxation region 36. Each p-type connection region 42 connects the electric field relaxation region 36 and the body region 32. That is, the electric field relaxation region 36 and the p-type column region 38a are connected to the source electrode 70 via each p-type connection region 42 and the body region 32.

The drift region 44 is of n-type and in contact with the SJ region 38 from the lower side. The n-type impurity concentration of the drift region 44 is lower than the n-type impurity concentrations of the n-type upper region 34, the n-type connection region 40, and the n-type column region 38b.

The drain region 46 is in contact with the drift region 44 from the lower side. The drain region 46 is exposed to the lower surface 12b of the semiconductor substrate 12. The drain region 46 is in ohmic contact with the drain electrode 72. The n-type impurity concentration of the drain region 46 is higher than the n-type impurity concentration of the drift region 44.

Next, the operation of the semiconductor device 10 will be described. When the semiconductor device 10 is in use, a voltage is applied to the drain electrode 72 higher than that applied to the source electrode 70. When a voltage equal to or higher than a gate threshold value is applied to the gate electrode 26, a channel is formed in the body region 32 in a range in contact with the gate insulating film 24, and the semiconductor device 10 is turned on. When the voltage applied to the gate electrode 26 is lowered to less than the gate threshold value, the channel disappears and the semiconductor device 10 is turned off.

When the semiconductor device 10 is in an off state, the potential of the drain electrode 72 is much higher than the potential of the source electrode 70. In this state, the n-type upper region 34 and the n-type connection region 40 have a potential close to that of the drain electrode 72. As described above, the electric field relaxation region 36 has a potential substantially equal to that of the source electrode 70. As a result, a depletion layer spreads from the electric field relaxation region 36 into the n-type upper region 34 and the n-type connection region 40. Since the electric field relaxation region 36 is located directly below the trench 22, the depletion layer extending from the electric field relaxation region 36 to the n-type upper region 34 can effectively suppress the electric field from concentrating near the lower end of the trench 22.

In this embodiment, the openings 37 provided in the electric field relaxation region 36 are arranged in dispersed manner along a plane (xy plane) parallel to the upper surface 12a of the semiconductor substrate 12. Therefore, the n-type connection region 40 can be more finely divided in the plane, compared to a comparative example in which the p-type region and the n-type region are arranged alternately in stripes. Therefore, even if the n-type impurity concentration in the n-type connection region 40 is increased, a depletion layer spreads from the electric field relaxation region 36 to almost the entire area of the n-type connection region 40 when the semiconductor device 10 is turned off. In this manner, in the semiconductor device 10, the n-type impurity concentration of the n-type connection region 40 can be made sufficiently high, so that the resistance of the n-type connection region 40, that is, the on-resistance, can be reduced. In this embodiment, the intervals d1 between the openings 37 are equal to each other, and the intervals d2 between the openings 37 are equal to each other. In this manner, since the openings 37 are regularly arranged in the plane, the on-resistance can be made uniform over the entire area of the semiconductor device 10.

Furthermore, when the semiconductor device 10 is in an off state, the n-type column region 38b of the SJ region 38 has a potential close to that of the drain electrode 72, and the p-type column region 38a of the SJ region 38 has a potential substantially equal to that of the source electrode 70. As a result, a high reverse voltage is applied to the pn junction at the interface between the p-type column region 38a and the n-type column region 38b. As a result, a depletion layer spreads laterally (in the xy plane direction) from the p-type column region 38a into the n-type column region 38b. Furthermore, the depletion layer spreads laterally from the n-type column region 38b into the p-type column region 38a. This depletion layer maintains the voltage applied between the drain electrode 72 and the source electrode 70.

The p-type column region 38a and the n-type column region 38b of the SJ region 38 extend linearly along the x direction and are arranged alternately in the y direction. In this manner, the p-type column regions 38a and the n-type column regions 38b are arranged in a striped pattern. Therefore, the p-type column regions 38a and the n-type column regions 38b (i.e., the SJ region 38) are likely to be uniformly depleted when the semiconductor device 10 is turned off. This allows the semiconductor device 10 to ensure a high breakdown voltage. Furthermore, in this semiconductor device 10, the p-type column regions 38a are provided at positions not overlapping with the openings 37. Therefore, the current path is not restricted by the p-type column regions 38a when the semiconductor device 10 is turned on. Thus, current flows suitably from the drain electrode 72 to the source electrode 70 via the n-type column region 38b, the n-type connection region 40, and the n-type upper region 34, and deterioration of the on-resistance is suppressed. As described above, in the semiconductor device 10 of this embodiment, a high breakdown voltage can be ensured and the on-resistance can be reduced.

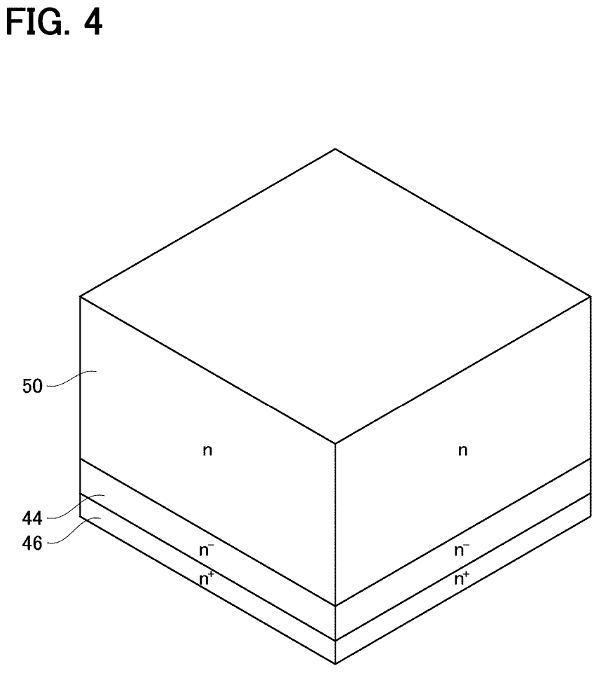

Next, a method for manufacturing the semiconductor device 10 will be described with reference to FIGS. 4 to 7. As shown in FIG. 4, a semiconductor substrate is prepared in which an n-type drift region 44 and an n-type semiconductor layer 50 having a higher n-type impurity concentration than the drift region 44 are formed in this order on an upper surface of an n-type drain region 46. The semiconductor substrate can be manufactured, for example, by epitaxially growing the drift region 44 and the semiconductor layer 50 in this order on the upper surface of the drain region 46.

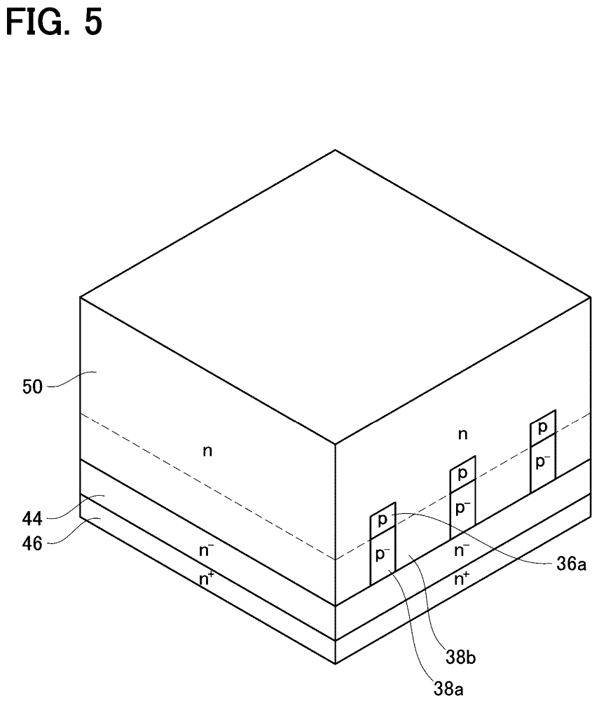

Next, as shown in FIG. 5, p-type impurities (for example, aluminum, etc.) are selectively ion-implanted from the upper surface of the semiconductor layer 50. As a result, plural p-type column regions 38a and plural x-direction portions 36a of the electric field relaxation region 36 shown in FIG. 2 are formed. The energy of implanting the p-type impurities is adjusted to form the p-type column regions 38a and the x-direction portions 36a so that the p-type column regions 38a are located below the corresponding x-direction portions 36a. Furthermore, the dose of the p-type impurity is adjusted to form the p-type column regions 38a and the x-direction portions 36a so that the p-type impurity concentration in the p-type column regions 38a is lower than the p-type impurity concentration in the x-direction portions 36a. In the depth range in which the p-type column region 38a is formed, the n-type semiconductor region adjacent to the p-type column region 38a becomes the n-type column region 38b.

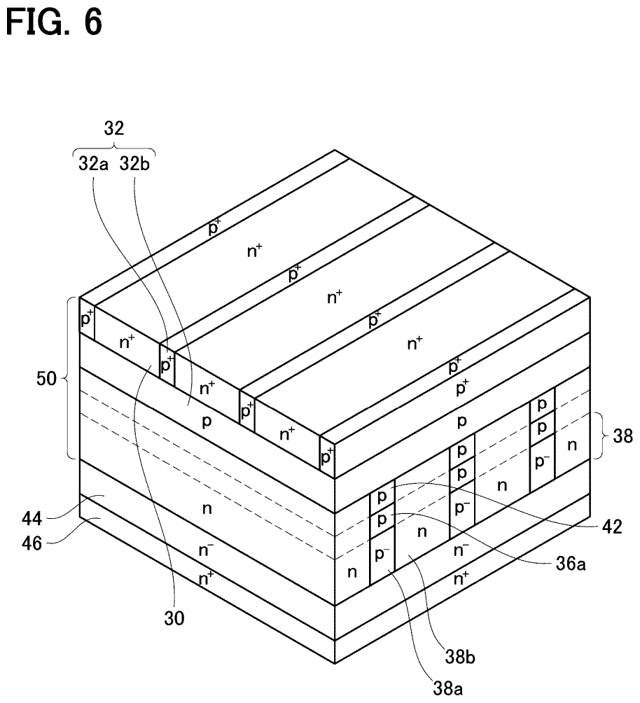

Next, as shown in FIG. 6, p-type impurities are ion-implanted from the upper surface of the semiconductor layer 50 to form the p-type connection regions 42 directly above the x-direction portions 36a. Next, the body region 32 and the source region 30 are formed by selectively ion-implanting p-type and n-type impurities, respectively.

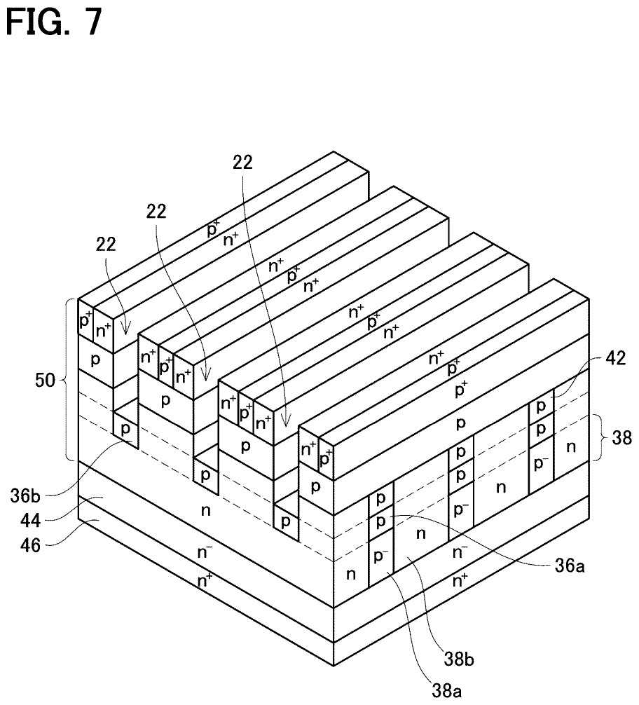

Next, as shown in FIG. 7, a trench 22 is formed in the upper surface of the semiconductor layer 50, and a p-type impurity is ion-implanted into the bottom of the trench 22 to form the y-direction portions 36b of the electric field relaxation region 36 shown in FIG. 2. The depth of the trench 22 and the implantation energy of the p-type impurity are adjusted so that the y-direction portions 36b are formed in the same depth range as the x-direction portions 36a. As a result, when the semiconductor layer 50 is viewed from the upper side, the electric field relaxation region 36 having the plural openings 37 is formed. In the depth range in which the electric field relaxation region 36 is formed, the n-type semiconductor region surrounded by the electric field relaxation region 36 becomes the n-type connection region 40. Thereafter, the gate insulating film 24, the gate electrode 26, the interlayer insulating film 28, the source electrode 70, and the drain electrode 72 are formed by a conventional method, thereby completing the semiconductor device 10 shown in FIG. 1.

### Second Embodiment

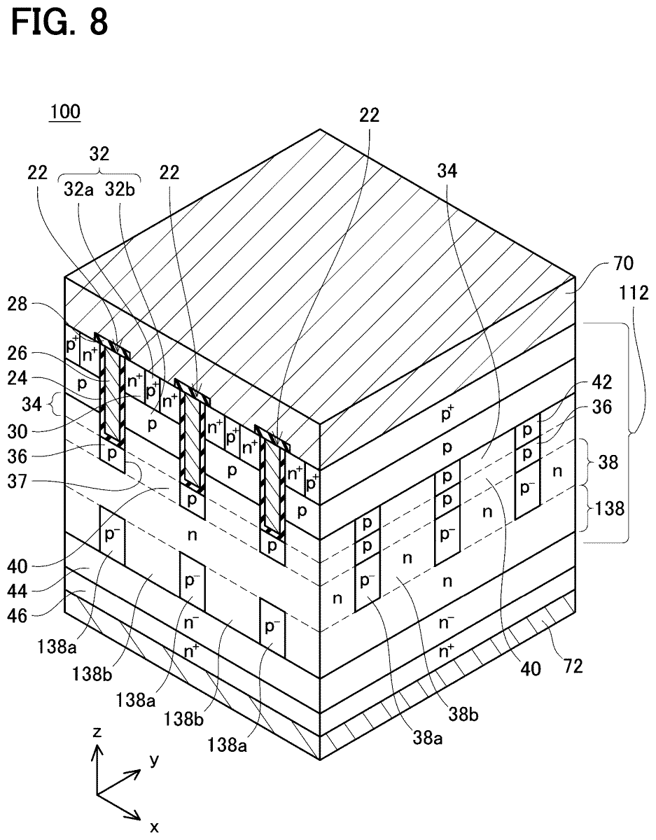

A semiconductor device 100 of the second embodiment further includes an SJ region 138 in comparison with the first embodiment. For ease of explanation, the SJ region 38 will be referred to as the first SJ region 38 and the SJ region 138 will be referred to as the second SJ region 138. In the second embodiment, as shown in FIG. 8, the second SJ region 138 is in contact with the first SJ region 38 from the lower side.

The second SJ region 138 has plural p-type column regions 138a and plural n-type column regions 138b. As shown in FIG. 8, when the semiconductor substrate 112 is viewed from the upper side, the p-type column region 138a and the n-type column region 138b extend linearly along the y direction and are alternately arranged in the x direction. That is, each of the p-type column regions 138a and the n-type column regions 138b extends linearly in a direction perpendicular to the p-type column regions 38a and the n-type column regions 38b of the first SJ region 38. Each p-type column region 138a is disposed in the lower part of the corresponding trench 22. Each p-type column region 138a is spaced apart from the y-direction portions 36b of the electric field relaxation region 36. The p-type impurity concentration of each p-type column region 138a is lower than the p-type impurity concentration of the electric field relaxation region 36. Each of the p-type column regions 138a is connected to each of the p-type column regions 38a. That is, the potential of each p-type column region 138a is approximately equal to the potential of the source electrode 70.

In the semiconductor device 100 of the second embodiment, by further providing the second SJ region 138, the overall length of the SJ region in the thickness direction (z direction) of the semiconductor substrate 112 can be increased, thereby ensuring a higher breakdown voltage. Furthermore, the p-type column region 38a and the n-type column region 38b are arranged to be perpendicular to the p-type column region 138a and the n-type column region 138b in the xy plane. Therefore, even if a positional deviation occurs between the first SJ region 38 and the second SJ region 138, the area of the current path can be restricted from varying.

### Third Embodiment

The semiconductor device 10, 100 is a vertical MOSFET having a trench gate structure in the first and second embodiments. A semiconductor device 200 of the third embodiment is a vertical MOSFET having a planar gate structure. The semiconductor device 200 includes a semiconductor substrate 212, electrodes, and an insulating film.

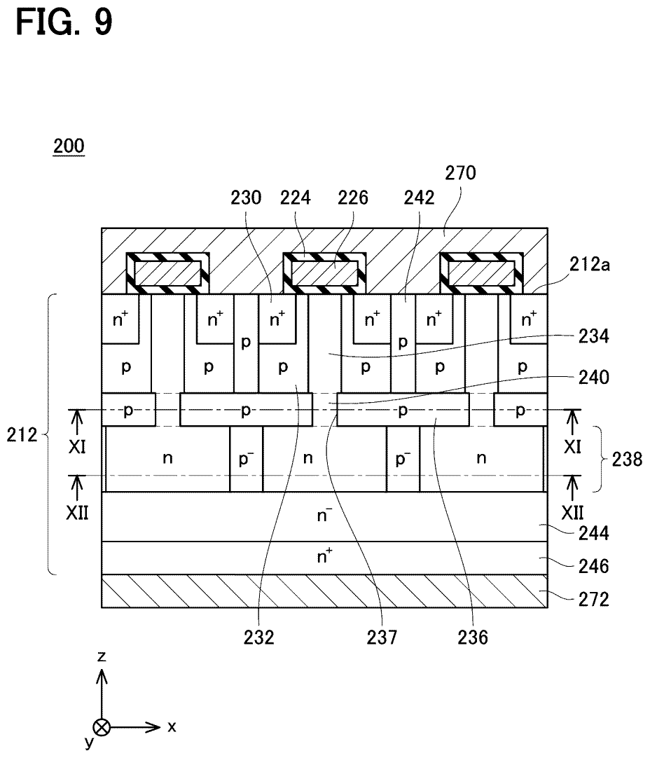

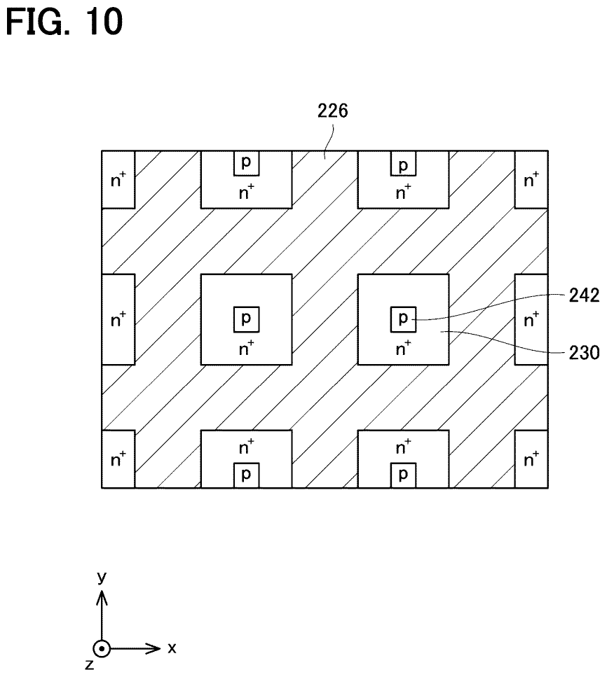

As shown in FIG. 9, a source electrode 270 and a gate electrode 226 are disposed on an upper surface 212a of the semiconductor substrate 212. The gate electrode 226 is disposed on the upper surface 212a of the semiconductor substrate 212 via a gate insulating film 224. The source electrode 270 is in contact with the upper surface 212a of the semiconductor substrate 212 in a portion where the gate insulating film 224 is not provided. The gate electrode 226 is insulated from the source electrode 270 by a gate insulating film 224. As shown in FIG. 10, the gate electrode 226 extends in a lattice pattern along the x direction and the y direction when the semiconductor substrate 212 is viewed from the upper side. In FIG. 10, illustration of the source electrode 270 is omitted.

The semiconductor substrate 212 includes source regions 230, body regions 232, an n-type upper region 234, an electric field relaxation region 236, an SJ region 238, n-type connection regions 240, p-type connection regions 242, a drift region 244, and a drain region 246.

Each source region 230 is exposed to the upper surface 212a of the semiconductor substrate 212. Each source region 230 is in ohmic contact with the source electrode 270.

Each body region 232 is exposed to the upper surface 212a of the semiconductor substrate 212. Each body region 232 extends from a position adjacent to a side of the source region 230 to an underside of the source region 230. The body region 232 is in ohmic contact with the source electrode 270.

The n-type upper region 234 is exposed to the upper surface 212a of the semiconductor substrate 212. The n-type upper region 234 is provided adjacent to the side of the body region 232. The n-type upper region 234 is separated from a corresponding source region 230 by the body region 232.

The gate electrode 226 opposes the n-type upper region 234 via the gate insulating film 224. The gate electrode 226 opposes the body region 232 located between the source region 230 and the n-type upper region 234.

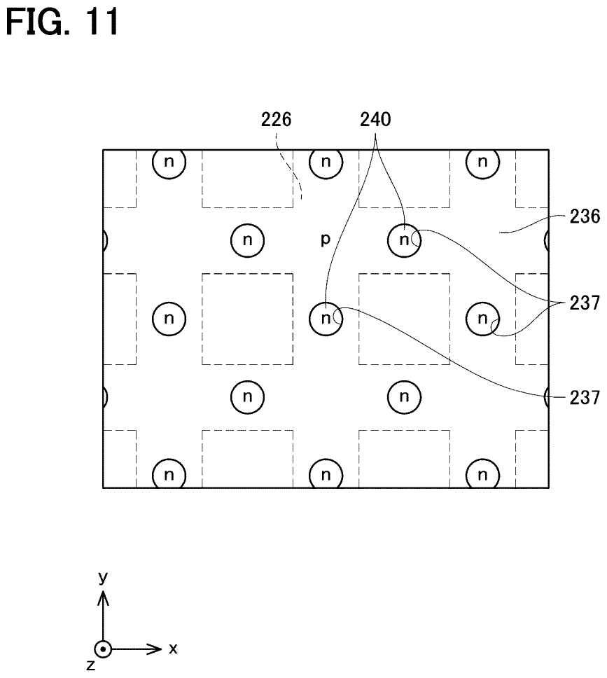

The electric field relaxation region 236 is disposed below the n-type upper region 234. As shown in FIG. 11, the electric field relaxation region 236 has plural openings 237 formed therein. Each opening 237 has a substantially circular shape when the semiconductor substrate 212 is viewed from the upper side, and is disposed in a dispersed manner within the plane shown in FIG. 11. Each opening 237 is provided at a position overlapping with the gate electrode 226 (that is, directly below the gate electrode 226) when the semiconductor substrate 212 is viewed from the upper side. Each opening 237 penetrates the electric field relaxation region 236 from its upper end to its lower end. The n-type connection region 240 is disposed within each opening 237.

The SJ region 238 is disposed below the electric field relaxation region 236. The SJ region 238 has plural p-type column regions 238a and plural n-type column regions 238b.

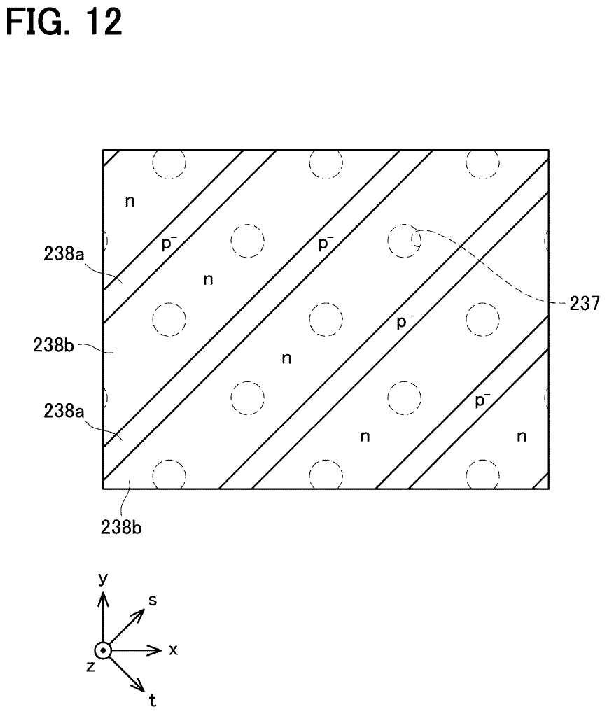

As shown in FIG. 12, when the semiconductor substrate 212 is viewed from the upper side, the p-type column region 238a and the n-type column region 238b extend linearly along an s direction intersecting both the x direction and the y direction, and are arranged alternately in a t direction perpendicular to the s direction. The p-type impurity concentration of each p-type column region 238a is lower than the p-type impurity concentration of the electric field relaxation region 236. Each p-type column region 238a is connected to the electric field relaxation region 236 directly below the electric field relaxation region 236. That is, when the semiconductor substrate 212 is viewed from the upper side, each p-type column region 238a does not overlap the opening 237. As in the first embodiment, the intervals between the adjacent openings 237 in the s direction are equal to each other, and the intervals between the adjacent openings 237 in the t direction are equal to each other.

Each n-type connection region 240 is disposed within the corresponding opening 237 as described above. The n-type impurity concentration of each n-type connection region 240 is higher than the n-type impurity concentration of the n-type upper region 234. The n-type impurity concentration of each n-type connection region 240 may be approximately equal to the n-type impurity concentration of the n-type upper region 234. Each n-type connection region 240 connects the n-type upper region 234 to the corresponding n-type column region 238b.

Each p-type connection region 242 extends from a position exposed to the upper surface 212a of the semiconductor substrate 212, through the source region 230 and the body region 232, and to the upper surface of the electric field relaxation region 236. Each p-type connection region 242 connects the source electrode 270 and the electric field relaxation region 236.

The configurations of the drift region 244 and the drain region 246 are the same as those in the first embodiment.

In the semiconductor device 200 of the third embodiment, similarly to the first embodiment, the electric field relaxation region 236 and the SJ region 238 can ensure a high breakdown voltage and reduce the on-resistance at the same time. In this embodiment, each opening 237 is provided at a position overlapping with the gate electrode 226 when the semiconductor substrate 212 is viewed from the upper side. That is, each opening 237 is provided at a position overlapping with the n-type upper region 234 opposing the gate electrode 226. Therefore, in this semiconductor device 200, the current path from the drain electrode 272 through the drain region 246, the drift region 244, the n-type column region 238b, the n-type connection region 240, and the n-type upper region 234 is short, thereby further reducing the on-resistance.

### Fourth Embodiment

A semiconductor device 300 of the fourth embodiment is a Schottky barrier diode, and includes a semiconductor substrate 312, electrodes, and the like.

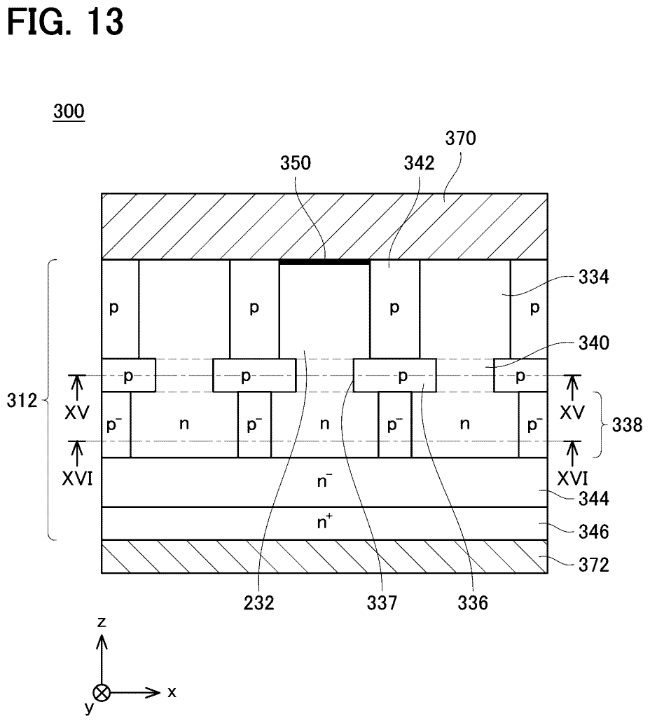

As shown in FIG. 13, an upper electrode 370 is provided on an upper surface 312a of a semiconductor substrate 312. The upper electrode 370 covers substantially the entire upper surface 312a of the semiconductor substrate 312.

The semiconductor substrate 312 includes an n-type upper region 334, an electric field relaxation region 336, an SJ region 338, plural n-type connection regions 340, plural p-type connection regions 342, a drift region 344, and an n-type region 346.

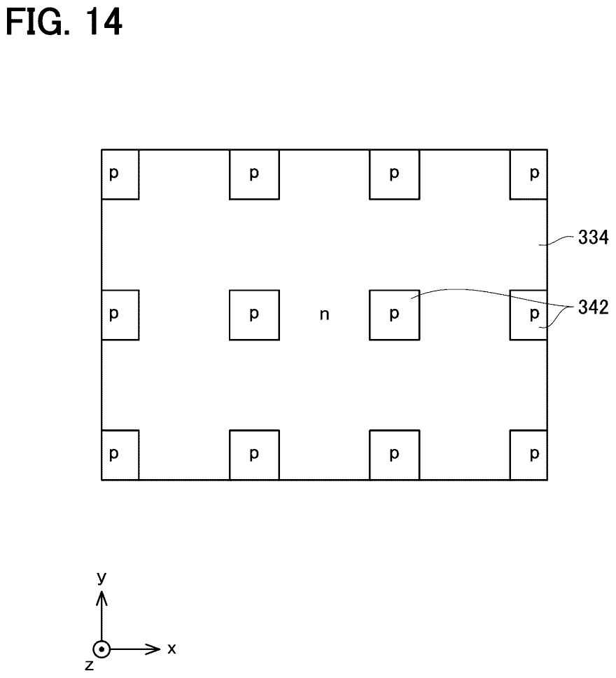

The n-type upper region 334 is exposed to the upper surface 312a of the semiconductor substrate 312. As shown in FIG. 14, the n-type upper region 334 extends in a lattice pattern along the x direction and the y direction when the semiconductor substrate 312 is viewed from the upper side. The n-type upper region 334 forms a Schottky junction with the upper electrode 370. In FIG. 14, the upper electrode 370 is omitted in illustration.

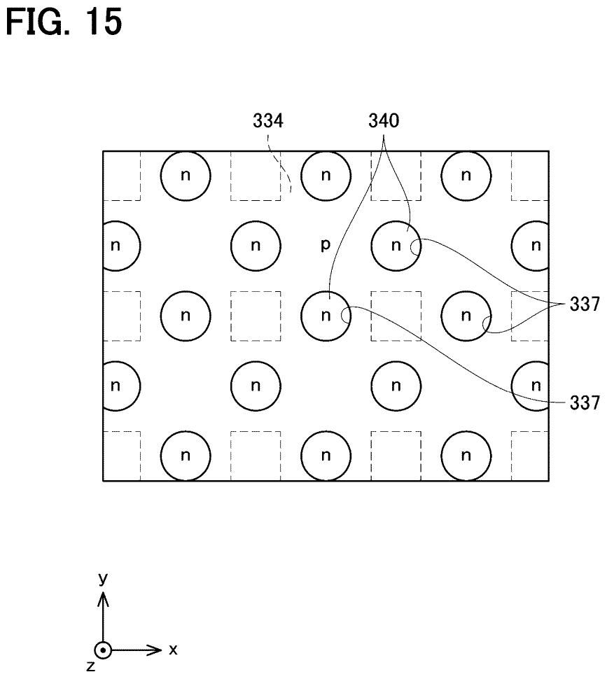

The electric field relaxation region 336 is disposed below the n-type upper region 334. As shown in FIG. 15, the electric field relaxation region 336 has plural openings 337 formed therein. Each opening 337 has a substantially circular shape when the semiconductor substrate 312 is viewed from the upper side, and is disposed in a dispersed manner within the plane shown in FIG. 15. When the semiconductor substrate 312 is viewed from the upper side, each opening 337 is provided at a position overlapping a Schottky junction surface 350 between the upper electrode 370 and the n-type upper region 334 (i.e., directly below the n-type upper region 334). Each opening 337 penetrates the electric field relaxation region 336 from its upper end to its lower end. An n-type connection region 340 is disposed within the opening 337.

The SJ region 338 is disposed below the electric field relaxation region 336. The SJ region 338 has plural p-type column regions 338a and plural n-type column regions 338b.

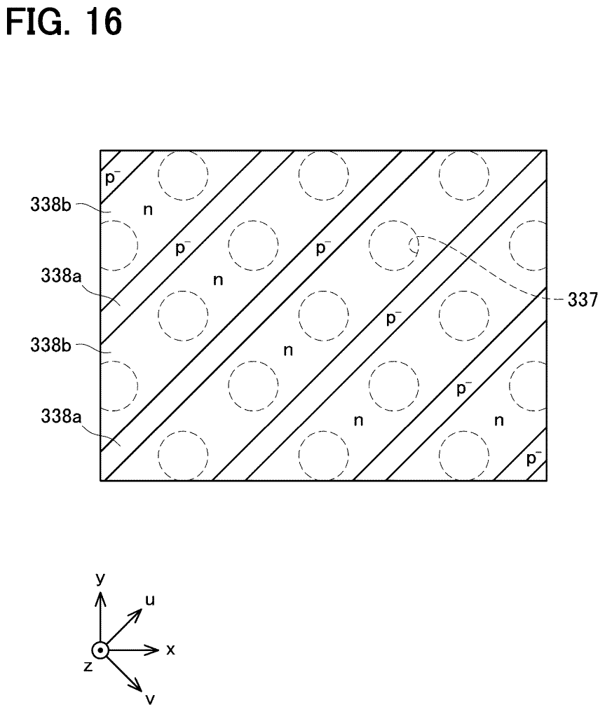

As shown in FIG. 16, when the semiconductor substrate 312 is viewed from the upper side, the p-type column region 338a and the n-type column region 338b extend linearly along the u direction intersecting both the x direction and the y direction, and are arranged alternately in the v direction perpendicular to the u direction. The p-type impurity concentration of each p-type column region 338a is lower than the p-type impurity concentration of the electric field relaxation region 336. Each p-type column region 338a is connected to the electric field relaxation region 336 directly below the electric field relaxation region 336. That is, when the semiconductor substrate 312 is viewed from the upper side, each p-type column region 338a does not overlap with the opening 337. As in the first embodiment, the intervals between the adjacent openings 337 in the u direction are equal to each other, and the intervals between the adjacent openings 337 in the v direction are equal to each other.

Each n-type connection region 340 is disposed within the corresponding opening 337 as described above. The n-type impurity concentration of each n-type connection region 340 is higher than the n-type impurity concentration of the n-type upper region 334. The n-type impurity concentration of each n-type connection region 340 may be approximately equal to the n-type impurity concentration of the n-type upper region 334. Each n-type connection region 340 connects the n-type upper region 334 to the corresponding n-type column region 338b.

Each p-type connection region 342 extends from a position exposed to the upper surface 312a of the semiconductor substrate 312 to the upper surface of the electric field relaxation region 336. Each p-type connection region 342 is provided adjacent to a side surface of the n-type upper region 334. Each p-type connection region 342 connects the upper electrode 370 and the electric field relaxation region 336.

The configurations of the drift region 344 and the n-type region 346 are similar to those of the drift region 44 and the drain region 46 in the first embodiment, respectively.

Next, the operation of the semiconductor device 300 will be described. When the semiconductor device 300 is in use, a higher voltage is applied to the upper electrode 370 than to the lower electrode 372. This lowers the Schottky barrier between the upper electrode 370 and the n-type upper region 334. As a result, electrons injected from the lower electrode 372 through the n-type region 346, the drift region 344, the n-type column region 338b, and the n-type connection region 340 into the n-type upper region 334 flow over the lowered Schottky barrier to the upper electrode 370, turning on the semiconductor device 300.

In the semiconductor device 300 of the fourth embodiment, similarly to the first embodiment, the electric field relaxation region 336 and the SJ region 338 can ensure a high breakdown voltage and reduce the on-resistance at the same time. In this embodiment, each opening 337 is provided at a position overlapping with the Schottky junction surface 350 when the semiconductor substrate 312 is viewed from the upper side. Therefore, in this semiconductor device 300, the current path from the Schottky junction surface 350 through the n-type upper region 334, the n-type connection region 340 in the opening 337, the n-type column region 338b, the drift region 344, and the n-type region 346 is short, and the on-resistance can be further reduced.

Although the embodiments have been described in detail above, these are merely examples and do not limit the scope of claims. The techniques described in claims include various modifications of the specific examples illustrated above.

In the first embodiment, the openings 37 are regularly arranged along the x direction and the y direction. However, the openings 37 may be arranged, for example, randomly in the plane shown in FIG. 2, if not overlapping with the p-type column regions 38a when the semiconductor substrate 12 is viewed from the upper side. The same applies to the other embodiments. Furthermore, the shape of the opening 37 etc. is not particularly limited. As in the embodiments, the shape may be rectangular or circular, or may be another shape.

The second SJ region 138 described in the second embodiment may be applied to the third and fourth embodiments.

In the second embodiment, the p-type column regions 138a and n-type column regions 138b of the second SJ region 138 do not have to be orthogonal to the p-type column regions 38a and n-type column regions 38b of the first SJ region 38. The p-type column regions 138a and the n-type column regions 138b only need to extend so as to intersect with the p-type column regions 38a and the n-type column regions 38b.

In the first embodiment, the p-type column region 38a of the SJ region 38 does not have to be in contact with the electric field relaxation region 36. The same applies to the other embodiments. In the second embodiment, the second SJ region 138 does not have to be in contact with the first SJ region 38.

In the first embodiment, the p-type connection region 42 does not necessarily have to be provided. The electric field relaxation region 36 may be connected to the source electrode 70 at a position not shown. The same applies to the other embodiments.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate;
an upper electrode provided on an upper surface of the semiconductor substrate; and
a lower electrode provided on a lower surface of the semiconductor substrate, wherein the semiconductor device is configured so that current flows between the upper electrode and the lower electrode,
the semiconductor substrate includes:
a first conductivity type upper region;
a second conductivity type electric field relaxation region located below the first conductivity type upper region and connected to the upper electrode;
a superjunction region located below the electric field relaxation region; and
a plurality of first conductivity type connection regions, wherein
the superjunction region has a plurality of first conductivity type column regions and a plurality of second conductivity type column regions,
when the semiconductor substrate is viewed from an upper side, the second conductivity type column region and the first conductivity type column region extend linearly along a first direction and are alternately arranged in a second direction perpendicular to the first direction,
the electric field relaxation region has a plurality of openings passing through the electric field relaxation region from an upper end to a lower end,
the plurality of openings is arranged in a distributed manner within a plane parallel to the upper surface of the semiconductor substrate,
the plurality of first conductivity type connection regions is respectively disposed within the plurality of openings to connect the first conductivity type upper region to the first conductivity type column region,
a concentration of second conductivity type impurity in each of the second conductivity type column regions is lower than that in the electric field relaxation region, and
when the semiconductor substrate is viewed from an upper side, the second conductivity type column regions do not overlap with the openings.

2. The semiconductor device according to claim 1, wherein
when the semiconductor substrate is viewed from an upper side, the openings are arranged to form a plurality of rows spaced apart from each other in the first direction,
the plurality of rows is spaced apart from each other in the second direction,
intervals between the openings adjacent to each other in the first direction are equal to each other, and
intervals between the rows adjacent to each other in the second direction are equal to each other.

3. The semiconductor device according to claim 1, wherein the superjunction region is a first superjunction region, further comprising:
a second superjunction region disposed below the first superjunction region, wherein
the second superjunction region has a plurality of first conductivity type column regions and a plurality of second conductivity type column regions,
when the semiconductor substrate is viewed from an upper side, the second conductivity type column region and the first conductivity type column region of the second superjunction region extend linearly along a third direction intersecting the first direction, and are alternately arranged in a fourth direction perpendicular to the third direction, and
a concentration of second conductivity type impurity in each of the second conductivity type column regions of the second superjunction region is lower than that in the electric field relaxation region.

4. The semiconductor device according to claim 1, further comprising a second conductivity type connection region extending upward from an upper surface of the electric field relaxation region to connect the electric field relaxation region to the upper electrode.

5. The semiconductor device according to claim 1, further comprising:
a trench provided on the upper surface of the semiconductor substrate;
a gate insulating film covering an inner surface of the trench; and
a gate electrode provided in the trench and insulated from the semiconductor substrate by the gate insulating film, wherein
the semiconductor substrate includes:
a first conductivity type source region exposed to the upper surface of the semiconductor substrate and in contact with the gate insulating film; and
a second conductivity type body region in contact with the gate insulating film below the source region to separate the first conductivity type upper region from the source region, and
the first conductivity type upper region is in contact with the gate insulating film below the body region.

6. The semiconductor device according to claim 5, wherein each of the openings does not overlap with the trench when the semiconductor substrate is viewed from an upper side.

7. The semiconductor device according to claim 1, further comprising:
a gate electrode provided on the upper surface of the semiconductor substrate via a gate insulating film, wherein
the semiconductor substrate includes:
a first conductivity type source region exposed to the upper surface of the semiconductor substrate; and
a second conductivity type body region provided adjacent to the source region and exposed to the upper surface of the semiconductor substrate,
the first conductivity type upper region is located adjacent to the body region, and is separated from the source region by the body region,
the first conductivity type upper region is exposed to the upper surface of the semiconductor substrate,
the gate electrode opposes the first conductivity type upper region via the gate insulating film, and
the gate electrode opposes the body region located between the source region and the first conductivity type upper region, via the gate insulating film.

8. The semiconductor device according to claim 7, wherein each of the openings overlaps with the gate electrode when the semiconductor substrate is viewed from an upper side.

9. The semiconductor device according to claim 1, wherein
the first conductivity type upper region is exposed to the upper surface of the semiconductor substrate, and
the upper electrode and the upper surface of the semiconductor substrate form a Schottky junction.

10. The semiconductor device according to claim 9, wherein each of the openings overlaps with a Schottky junction surface when the semiconductor substrate is viewed from an upper side.
